(19) United States
(12) Patent Application Publication
(10) Pub. No.: US 2023/0155057 A1
(43) Pub. Date: May 18, 2023

(54) Semiconductor Component and Process for Manufacturing a Semiconductor Component

(71) Applicant: ams-OSRAM International GmbH, Regensburg (DE)

(72) Inventor: Laura Kreiner, Regensburg (DE)

(21) Appl. No.: 17/995,822

(22) PCT Filed: Apr. 1, 2021
(86) PCT No.: PCT/EP2021/058573

§ 371 Date: Oct. 7, 2022

(30) Foreign Application Priority Data
Apr. 8, 2020 (DE) 10 2020 204 537.2

(51) Int. Cl. H01L 33/10; H01L 33/50; H01L 33/00

(52) U.S. Cl. CPC H01L 33/10; H01L 33/0075; H01L 33/501; H01L 2933/0041

(57) ABSTRACT

In an embodiment a semiconductor component includes a semiconductor body having an active region and an emission area, a first dielectric mirror layer, a converter layer configured to convert radiation generated in the semiconductor component to radiation of a second wavelength rang and a second dielectric mirror layer, wherein the first dielectric mirror layer and the converter layer are arranged between the emission area and the second dielectric mirror layer, wherein the first dielectric mirror layer is transmissive for radiation of a first wavelength range incident at angles of incidence in a predetermined first angular range and reflective for radiation of the first wavelength range incident at angles of incidence in a predetermined second angular range, and wherein the second dielectric mirror layer is transmissive for radiation of the second wavelength range incident at angles of incidence in the first angular range and reflective for radiation of the second wavelength range incident at angles of incidence in the second angular range.

This patent application is a national phase filing under section 371 of PCT/EP2021/058573, filed Apr. 1, 2021, which claims the priority of German patent application 102020204537.2, filed Apr. 8, 2020, each of which is incorporated herein by reference in its entirety.

### TECHNICAL FIELD

A semiconductor component is provided. In addition, a method for manufacturing a semiconductor component is provided.

### SUMMARY

Embodiments provide a semiconductor component which comprises a better directional radiation characteristic. Further embodiments provide a method for manufacturing such a semiconductor component.

According to at least one embodiment, the semiconductor component generates and emits radiation of a first and of a second wavelength range during operation.

For example, the second wavelength range is red-shifted relative to the first wavelength range. For example, the first wavelength range is a region from the blue spectral range. The second wavelength range is, for example, a region from the yellow and/or red spectral range. For example, the total radiation emitted from the semiconductor component is perceived as white light by a human observer. The semiconductor component can be used, for example, in lighting devices or headlights, for example, front headlights of a motor vehicle, or as display backlight, for example, of a smartphone.

Alternatively, the first wavelength range can be a range from the red spectral range and/or IR spectral range. Then, the second wavelength range is preferably a region in the IR spectral range. In this case, the semiconductor component can be used for spectrometer applications or sensor applications, for example.

The first and the second wavelength range preferably do not overlap with each other. For example, the radiation emitted by the semiconductor component comprises a first peak in the first wavelength range and a second peak in the second wavelength range, wherein the two peaks are spaced apart by, for example, at least 50 nm or at least 100 nm.

According to at least one embodiment of the semiconductor component, the semiconductor component comprises a semiconductor body with an active region. The semiconductor body comprises, for example, a p-type region and an n-type region, wherein the active region is arranged between the p-type region and the n-type region. The active region is configured to generate electromagnetic primary radiation. In particular, the active region includes at least one quantum well structure in the form of a single quantum well, short SQW, or in the form of a multi-quantum well structure, short MQW. In addition, the active region includes one, preferably several, secondary well structures.

The primary radiation comprises, for example, wavelengths from a wavelength range between and including the IR region and the UV region. In particular, the primary radiation is radiation in the blue or green or red spectral range or in the UV region or in the IR region. The primary radiation is, in particular, incoherent radiation. The radiation of the first wavelength range is the primary radiation, for example. Alternatively, the radiation of the first wavelength range can be radiation, which is generated by conversion of the primary radiation in the semiconductor component.

The semiconductor body is based on a nitride compound semiconductor material, for example, such as AlnIn1-n-mGamN, for example, or on a phosphide compound semiconductor material, such as AlnIn1-n-mGamP, for example, or on an arsenide compound semiconductor material, such as AlnIn1-n-mGamAs, for example, wherein 0 ≤ n ≤ 1, 0 ≤ m ≤ 1, and m + n ≤ 1, respectively. Thereby, the semiconductor body can comprise dopants as well as additional constituents. For simplicity, however, only the essential constituents of the crystal lattice of the semiconductor body, i.e. Al, As, Ga, In, N or P, are specified, even if these can be partially replaced and/or supplemented by small amounts of additional substances.

For example, the semiconductor component is a radiation-emitting semiconductor component, for example a light-emitting diode, which can be used in particular as a radiation source. For example, the semiconductor component is a semiconductor chip, in particular a light-emitting diode chip, preferably a thin-film light-emitting diode chip, wherein a growth substrate of the semiconductor body is removed.

According to at least one embodiment of the semiconductor component or its embodiment described above, the semiconductor body comprises an emission area. For example, more than 50% or more than 70%, preferably more than 90% of the total electromagnetic radiation emitted by the semiconductor body is emitted via the emission area. A main extension plane of the emission area is preferably parallel to a main extension plane of the active region.

The semiconductor body can be pixelated, such that the semiconductor body comprises several individually and independently controllable emission regions (pixels). The emission regions can be defined and separated from each other by trenches in the semiconductor body. During operation of the emission regions, radiation is emitted over a partial area of the emission area assigned to each such emission region. For example, the semiconductor body and/or the semiconductor component are divided into at least four or at least ten or at least 50 emission regions.

According to at least one embodiment of the semiconductor component, the semiconductor component comprises a first dielectric mirror layer. For example, the first dielectric mirror layer is formed with a plurality of dielectric layers. For example, the dielectric layers form a layer stack with more than four or more than ten or more than 50 or more than 100 layers. For example, high refractive index layers alternate with low refractive index layers in the layer stack. By a “low refractive index layer” is meant here and in the following a layer formed with a material, which comprises a lower refractive index than the material from which the high refractive index layers are formed. For example, the materials of the low refractive index layers comprise a refractive index of at most 2. For example, the materials of the high refractive index layers comprise a refractive index of at least 2.3. The low refractive index layers comprise, for example, at least one of the following materials: SiO2, SiN, SiON, MgF2. The high refractive index layers comprise, for example, at least one of the following materials: Nb2O₅, TiO2, ZrO2, HfO2, Al2O₃, Ta2O₅, ZnO. The refractive index refers in particular to the primary radiation, which is generated in the active region during the intended operation.

For example, the low refractive index layers and the high refractive index layers alternate periodically. This means that within the layer stack, each low refractive index layer is followed by a high refractive index layer. For example, the high refractive index layers each have the same layer thickness and the low refractive index layers each have the same layer thickness. The layer thickness is measured perpendicular to the main extension plane of the active region. For example, the layer thickness is between and including 10 nm and 500 nm. Further, for example, all low refractive index layers comprise the same material among each other and all high refractive index layers comprise the same material among each other. In particular, the dielectric mirror layer is a so-called Bragg mirror.

Alternatively, the low refractive index and high refractive index layers alternate aperiodically. This is understood here and in the following to mean that within the layer stack high refractive index and low refractive index layers alternate. The layer thickness of each layer is, in particular, determined individually. The layer thickness of each layer is, for example, between and including 10 nm and 500 nm. Further, the materials of the high refractive index layers and the low refractive index layers can each vary among each other.

Preferably, a refractive index difference between a high refractive index layer and a low refractive index layer is at least 0.2 or 0.3 or 0.5 or 0.8 or 1.

According to at least one embodiment of the semiconductor component or its embodiments described above, the semiconductor component comprises a converter layer for converting radiation generated in the semiconductor component into radiation of the second wavelength range.

In the intended operation of the semiconductor component, in particular radiation of the first wavelength range and/or primary radiation is partially converted into radiation of the second wavelength range within the converter layer.

According to at least one embodiment of the semiconductor component or its embodiments described above, the semiconductor component comprises a second dielectric mirror layer. All features disclosed for the first mirror layer are also disclosed for the second mirror layer. Preferably, the second dielectric mirror layer is also formed by a layer stack comprising a plurality of dielectric layers. The first and second dielectric mirror layers can differ, for example, in the number of dielectric layers and/or their layer thicknesses.

According to at least one embodiment of the semiconductor component or its embodiment described above, the first dielectric mirror layer and the converter layer are arranged between the emission area and the second dielectric mirror layer.

According to at least one embodiment of the semiconductor component or its embodiments described above, the first dielectric mirror layer is transmissive for radiation of the first wavelength range incident at angles of incidence in a predetermined first angular range and reflective for radiation of the first wavelength range incident at angles of incidence in a predetermined second angular range. The first angular range and the second angular range preferably do not overlap. For radiation of the second wavelength range, the first dielectric mirror layer is, for example, transmissive at all angles of incidence.

According to at least one embodiment of the semiconductor component or its embodiments described above, the second dielectric mirror layer is transmissive for radiation of the second wavelength range incident at angles of incidence in the first angular range and reflective for radiation of the second wavelength range incident at angles of incidence in the second angular range.

By “transmissive” it is understood here and in the following that an element transmits or passes at least 75%, preferably at least 90%, particularly preferably at least 99% of a radiation. By “reflective” it is understood that an element reflects more than 75%, preferably at least 90%, particularly preferably at least 99% of a radiation.

An angle of incidence is measured here and in the following against a normal of the respective dielectric mirror layer. By a normal of a dielectric mirror layer is meant a normal of the main plane of extension of the dielectric mirror layer.

The expressions “predetermined first angular range” and “predetermined second angular range” refer to the fact that the materials and/or the layer thicknesses of a dielectric mirror layer are selected so that the angular range in which it is transmissive and the angular range in which it is reflective can be set precisely and almost arbitrarily.

Since a dielectric mirror is usually optimized for radiation of one wavelength, respectively a narrow range around this wavelength, the specifications given here and in the following regarding the reflection and transmission of a mirror for a radiation of a wavelength range refers in particular to the wavelength at which the radiation of this wavelength range has an intensity maximum.

In at least one embodiment, during operation, the semiconductor component generates and emits radiation of a first and a second wavelength range. The semiconductor component comprises a semiconductor body with an active region for generating electromagnetic primary radiation and an emission area. Further, the semiconductor component comprises a first dielectric mirror layer, a converter layer for converting radiation generated in the semiconductor component to radiation of the second wavelength range, and a second dielectric mirror layer. The first dielectric mirror layer and the converter layer are arranged between the emission area and the second dielectric mirror layer. The first dielectric mirror layer is transmissive for radiation of the first wavelength range incident at angles of incidence in a predetermined first angular range, and reflective for radiation of the first wavelength range incident at angles of incidence in a predetermined second angular range. The second dielectric mirror layer is transmissive for radiation of the second wavelength range incident at angles of incidence in the first angular range and reflective for radiation of the second wavelength range incident at angles of incidence in the second angular range.

A semiconductor component described herein is based on the following technical features, among others. Conventional radiation sources, which use light-emitting diode chips have a Lambertian radiation characteristic. In applications, where only a narrow angular range can be used, the radiation from such a radiation source can partially not be used. In these so-called Etendue-limited applications, the efficiency can be increased by a directional radiation characteristic of the radiation source, wherein in particular the luminance along a surface normal of a radiation area is increased.

Traditionally, additional lenses are installed or required for this purpose. This requires a more complex manufacturing process if the lenses are installed on the radiation source side and a more complex alignment process if the lenses are used on the Etendue-limited application side. Alternatively, semiconductor laser diodes can be used as radiation source, as they comprise directional radiation characteristics. It is thereby disadvantageous that due to the use of laser diodes so-called speckle patterns are formed, which are undesirable in many applications.

The semiconductor component described herein makes use, among other things, of the idea of obtaining a directional radiation characteristic by using two dielectric mirror layers. Thereby, the mirror layers are designed in such a way that radiation, which impinges on the mirror layers at a large angle of incidence is reflected, while radiation, which impinges on the mirror layers at a small angle of incidence is transmitted. The reflected radiation is reflected within the semiconductor body and/or the conversion element and impinges on the mirror layers again at a different angle of incidence, for example, due to redistribution processes within the semiconductor body and/or conversion element, such as scattering and reflection. With this the initially reflected radiation from the semiconductor component can finally be emitted in the desired angular range. By using two dielectric mirror layers also white light, i.e. radiation with a broad spectral distribution, can be emitted directionally.

Thereby, radiation of the first wavelength range is directed through the first dielectric mirror layer and radiation of the second wavelength range is directed through the second dielectric mirror layer. As the converter does not convert all of the radiation incident on it, but only a portion, in the intended operation the semiconductor component directionally emits mixed light, which comprises radiation of the first and second wavelength range. A narrow-angle radiation characteristic can be obtained, which is improved compared to a Lambertian radiation characteristic. Such an improved radiation characteristic is also known as “superlambertian emission”.

Advantageously, thus, the semiconductor component described herein can be used in part or in its entirety in a radiation source for optical applications which are Etendue-limited. These applications include, for example, projection systems or automobile headlights. Thereby, advantageously, optical components for generating the directional radiation characteristic can be omitted, allowing for more compact and less expensive semiconductor components. Alternatively, by a combination of such optical components with an enlarged radiation area of the semiconductor component with an improved radiation characteristic an increase in the luminance in the application can be achieved. Further advantageously, a combination of first dielectric mirror layer, converter layer and second dielectric mirror layer described herein does not form an optical resonator. In particular, due to the arrangement of the first dielectric mirror layer, the converter layer and the second dielectric mirror layer described herein no laser radiation is generated. Thus, the occurrence of speckle patterns can be advantageously prevented.

According to at least one embodiment of the semiconductor component or one of its embodiments described above, the first angular range comprises all angles of incidence between 0° and α, inclusive, measured to a normal of the respective dielectric mirror layers. Thus, the first angular range forms a cone with the normal as the axis of rotation and an aperture angle of 2·α. α, for example, has a value of at most 75° or at most 60° or at most 45° or at most 30°. Alternatively or additionally, the value for α is, for example, at least 5° or at least 10°.

According to at least one embodiment of the semiconductor component or one of its embodiments described above, the second angular range comprises all angles of incidence of at least β measured with respect to the normal of the respective dielectric mirror layer, wherein β > α holds. Preferably, β is at least 1° or at least 5° or at least 10° greater than a. Alternatively or additionally, β is at most 10° or at most 5° greater than a. Preferably, the second angular range comprises all angles of incidence between and including β and 90°.

According to at least one embodiment of the semiconductor component or one of its embodiments described above, the first dielectric mirror layer comprises a transmittance of at least 75% or at least 90% or at least 99% for radiation of the first wavelength range incident at angles of incidence in the first angular range and a reflectance of at least 75% or at least 90% or at least 99% for radiation of the first wavelength range incident at angles of incidence in the second angular range. The specified values of the transmittance and the reflectance for radiation of the first wavelength range particularly preferably apply to all angles of incidence in the respective angular range.

According to at least one embodiment of the semiconductor component or one of its embodiments described above, the second dielectric mirror layer has a transmittance of at least 75% or at least 90% or at least 99% for radiation of the second wavelength range incident at angles of incidence in the first angular range and a reflectance of at least 75% or at least 90% or at least 99% for radiation of the second wavelength range incident at angles of incidence in the second angular range. The specified values of the transmittance and the reflectance for radiation of the second wavelength range particularly preferably apply to all angles of incidence in the respective angular range.

According to at least one embodiment of the semiconductor component or one of its embodiments described above, the emission area of the semiconductor body comprises an outcoupling structure. For example, this surface is roughened. Advantageously, the outcoupling structure can improve the radiation outcoupling from the semiconductor body.

According to at least one embodiment of the semiconductor component or one of its embodiments described above, a planarization layer is arranged at the outcoupling structure, wherein the planarization layer completely fills the outcoupling structure. The planarization layer comprises a smooth main surface facing away from the outcoupling structure. By “smooth” is meant here and in the following that said surface comprises a low roughness of, for example, less than 1 nm or less than 0.5 nm, preferably less than 0.2 nm.

The planarization layer comprises, in particular, a material comprising a refractive index that differs from the refractive index of the semiconductor body by at least 0.2 or 0.3 or 0.5 or 1. For example, the material of the planarization layer is silicon dioxide (SiO2). Alternatively, the planarization layer can comprise silicone. In this case, the planarization layer can comprise the properties of an adhesive. The material of the planarization layer is preferably transparent for radiation of the first wavelength range and/or primary radiation.

According to at least one embodiment of the semiconductor component or one of its embodiments described above, the converter layer is arranged between the first dielectric mirror layer and the second dielectric mirror layer. For example, the first dielectric mirror layer is in direct contact with the planarization layer. The converter layer is, for example, in direct contact with the first dielectric mirror layer and the second dielectric mirror layer.

Preferably, each surface to which the first or the second mirror layer is applied to is smooth. Advantageously, the first dielectric mirror layer and the second dielectric mirror layer can be applied particularly precisely to smooth surfaces. Due to a precise application of the layers, each with a specified layer thickness, it is, in particular, possible to realize dielectric mirror layers with desired transmission and reflection properties.

According to at least one embodiment of the semiconductor component or one of its embodiments described above, the first dielectric mirror layer is arranged between the converter layer and the second dielectric mirror layer. For example, the converter layer is in direct contact with the emission area of the semiconductor body or with the planarization layer. For example, the first dielectric mirror layer is in direct contact with the converter layer and/or with the second dielectric mirror layer. Preferably, a surface of the converter layer facing away from the emission area is smooth.

According to at least one embodiment of the semiconductor component or one of its embodiments described above, a third mirror layer is arranged at a surface of the semiconductor body opposite the emission area. The third mirror layer comprises, for example, a dielectric mirror, preferably a Bragg mirror, and/or a metallic mirror. The metallic mirror comprises, for example, aluminum or silver or gold, or an alloy, such as an Al/Ag alloy. For example, the Bragg mirror comprises for radiation of the first and/or second wavelength range and/or primary radiation with angles of incidence greater than or equal to 40° or greater than or equal to 30° or greater than or equal to 10°, a reflectivity of at least 80% or at least 90% or at least 95%. The metallic mirror comprises for example for radiation of the first and/or second wavelength range and/or primary radiation with angles of incidence less than or equal to 10° or less than or equal to 30° or less than or equal to 40° a reflectivity of at least 80% or at least 90% or at least 95%.

Advantageously, by a combination of a dielectric mirror with a metallic mirror, the reflectivity of the third mirror layer for radiation of the first and/or second wavelength range and/or primary radiation can be formed high regardless of the angle of incidence. By arranging a third mirror layer, advantageously, radiation loss can be reduced, as electromagnetic radiation which would leave the semiconductor body in the intended operation of the semiconductor component at the surface opposite to the emission area is reflected at the third mirror layer.

According to at least one embodiment of the semiconductor component or one of its embodiments described above, a fourth mirror layer is arranged on side surfaces of the semiconductor body. Side surfaces of the semiconductor body connect the emission area with the surface opposite to the emission area. All features disclosed for the third mirror layer are also disclosed for the fourth mirror layer, and vice versa. Advantageously, due to the arrangement of a fourth mirror layer further radiation loss can be reduced, especially for semiconductor components having an extension parallel to the main extension plane of the active region which is less than 100 µm.

According to at least one embodiment of the semiconductor component or one of its embodiments described above, the converter layer comprises a thickness between 5 µm and 500 µm, inclusive. Thereby, the thickness is measured perpendicular to the main extension plane of the active region. Advantageously, due to a converter layer having a thickness in the above-mentioned range scattering of radiation in directions parallel to the main extension plane of the active region is reduced.

According to at least one embodiment of the semiconductor component or one of its embodiments described above, the converter layer comprises converter particles, which are embedded in an inorganic matrix material. A surface of the converter layer facing away from the semiconductor body is thereby in particular smooth. The converter particles are, for example, quantum dots or phosphors. The matrix material is for example a cured sol-gel material or a so-called water glass. Advantageously, such an inorganic matrix material can be processed, for example grinding or polishing, whereby a smooth surface can be produced.

According to at least one embodiment of the semiconductor component or one of its embodiments described above, the converter layer is ceramic. A surface of the converter layer facing away from the semiconductor body is in particular smooth. Alternatively or additionally, a surface of the converter layer facing the semiconductor body is smooth. In particular, the converter layer is self-supporting and, for example, formed in the form of a platelet.

According to at least one embodiment of the semiconductor component or one of its embodiments described above, a glass body is arranged on a surface of the second dielectric mirror layer facing away from the converter layer. Preferably, the glass body is transparent for radiation of the first and second wavelength ranges. For example, the glass body is part of a housing or an encapsulation. For example, the glass body is configured for beam shaping. In particular, the glass body is a lens. Advantageously, due to a glass body, the semiconductor component is particularly protected from environmental influences. Further advantageously, due to the glass body the radiation characteristics of the semiconductor component can further be influenced.

According to at least one embodiment of the semiconductor component or one of its embodiments described above, the first mirror layer and the second mirror layer are integrally formed as an optical element. For example, the first dielectric mirror layer and the second dielectric mirror layer are indistinguishable from each other based on their material composition. In particular, the first dielectric mirror layer and the second dielectric mirror layer are deposited in a common manufacturing process. By a suitable choice of materials, layer sequences and/or layer thicknesses, an optical element can be provided that combines the advantageous transmission and reflection properties of the first dielectric mirror layer and the second dielectric mirror layer described above. Advantageously, a semiconductor component, wherein the first and second dielectric mirror layer are formed as a common optical element can be manufactured particularly cost-effectively and efficiently.

A method for manufacturing a semiconductor component is further disclosed. The semiconductor component described herein and embodiments thereof may, in particular, be manufactured by the method. This means, all features disclosed for the semiconductor component are also disclosed for the method, and vice versa.

According to at least one embodiment of the method, in a step A) at least one semiconductor body is provided. The semiconductor body comprises in particular an active region for generating electromagnetic primary radiation. For example, the semiconductor body is provided on a carrier.

According to at least one embodiment of the method or its embodiment described above, in a step B) a first dielectric mirror layer is deposited on an emission area of the semiconductor body.

The first dielectric mirror layer is transmissive for radiation of a first wavelength range incident at angles of incidence in a predetermined first angular range and reflective for radiation of the first wavelength range incident at angles of incidence in a predetermined second angular range.

For example, the first dielectric mirror layer is deposited on the emission area or applied by means of coating or sputtering. For example, a planarization layer is previously arranged at the emission area, which is then polished or grinded so that its surface facing away from the semiconductor body is smooth. Alternatively, the planarization layer can be applied in liquid and then be cured, whereby a smooth surface is formed. The material of the planarization layer can be a so-called spin-on-glass material. The provided semiconductor body comprises, for example, outcoupling structures at its emission area. A third mirror layer, for example, is arranged on a surface of the semiconductor body opposite the emission area.

Preferably, all surfaces and/or sides to which a dielectric mirror layer is directly applied to here and in the following are previously smoothed.

According to at least one embodiment of the method or its embodiments described above, in a step C) a converter layer is deposited on the emission area. The converter layer is configured to convert radiation generated in the semiconductor component into radiation of a second wavelength range.

According to at least one embodiment of the method or embodiments thereof described above, in a step D) a second dielectric mirror layer is deposited on the emission area. The second dielectric mirror layer is transmissive to radiation of the second wavelength range incident at angles of incidence in the first angular range and reflective for radiation of the second wavelength range incident at angles of incidence in the second angular range. In particular, the second dielectric mirror layer is deposited by the same methods as the first dielectric mirror layer.

According to at least one embodiment of the method or embodiments thereof described above, steps B), C), and D) are carried out in the indicated order, so that the converter layer is arranged between the first dielectric mirror layer and the second dielectric mirror layer.

According to at least one embodiment of the method or embodiments thereof described above, step B) is carried out after step C) and before step D), so that the first dielectric mirror layer is arranged between the converter layer and the second dielectric mirror layer.

According to at least one embodiment of the method or embodiments thereof described above, the first dielectric mirror layer is deposited on a first side of the converter layer. The second dielectric mirror layer is preferably deposited on a second side of the converter layer opposite the first side. Subsequently, the composite of the converter layer and the dielectric mirror layers is applied on the emission side, in particular to the planarization layer. The converter layer is in particular ceramic and self-supporting. In particular, the dielectric mirror layers, the converter layer and the composite can each be applied directly.

According to at least one embodiment of the method or embodiments thereof described above, a carrier element is provided. The second dielectric layer is applied to the carrier element. Subsequently, in particular, the composite comprising the carrier element and the second dielectric mirror layer is applied to the emission area. For example, the carrier element is a carrier foil or comprises a glass body.

For example, the converter layer is applied to the carrier element after the second dielectric mirror layer. Subsequently, the first dielectric mirror layer can be applied to the converter layer.

Alternatively, for example, the first dielectric mirror layer is applied to the emission side, in particular to the planarization layer. Subsequently, the converter layer can be applied to the first dielectric mirror layer.

For example, the second dielectric mirror layer and/or the converter layer are applied by means of deposition, coating or sputtering. In particular, in this embodiment, the dielectric mirror layers, the converter layer and the composite can each be applied directly.

According to at least one embodiment of the method or its embodiment described above, in an additional method step E) the carrier element is removed. For example, the carrier foil is peeled off.

According to at least one embodiment of the method or its embodiment described above, in step A) a composite of a plurality of semiconductor bodies is provided. Preferably, after steps B) to D), the composite of semiconductor bodies is singulated. For example, the composite is formed by a continuous semiconductor layer sequence. Alternatively, it is possible that the composite is formed by a plurality of semiconductor bodies which are provided spaced apart on a common carrier and are interconnected by the carrier. In this case, the carrier in particular is cut during singulation.

According to at least one embodiment of the method or embodiments thereof described above, trenches are introduced into the semiconductor component. The trenches extend in particular from a side of the second dielectric mirror layer facing away from the semiconductor body into the semiconductor body. Preferably, pixels of the semiconductor component are defined by the trenches. The trenches are introduced, for example, by an etching method, preferably by a lithographically defined etching method, such as plasma etching.

### BRIEF DESCRIPTION OF THE DRAWINGS

Further advantages and advantageous embodiments and further developments of the semiconductor component and the method result from the exemplary embodiments shown below in connection with schematic drawings. Identical, similar or identically acting elements are provided with the same reference signs in the figures. The figures and the proportions of the elements shown in the figures are not to be regarded as true to scale. Rather, individual elements may be represented exaggeratedly large for better representability and/or for better comprehensibility. It shows:

FIGS. 1 to 3 exemplary embodiments of the semiconductor component in sectional view,

FIGS. 4A to 4D sectional views of semiconductor components in various method stages of a first exemplary embodiment of a method for manufacturing a semiconductor component,

FIGS. 5A to 5E sectional views of semiconductor components in various method stages of a second exemplary embodiment of a method for manufacturing a semiconductor component, and

FIG. 6 is a sectional view of a wafer composite produced by the method according to FIGS. 4A to 4D.

### DETAILED DESCRIPTION OF ILLUSTRATIVE EMBODIMENTS

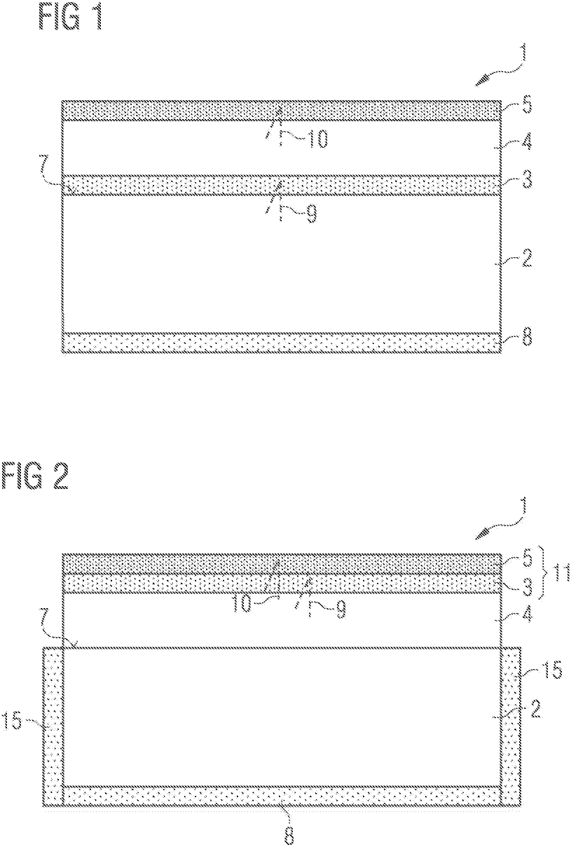

The semiconductor component 1 of FIG. 1 comprises a semiconductor body 2, a first dielectric mirror layer 3, a converter layer 4 and a second dielectric mirror layer 5. The first dielectric mirror layer 3 is arranged on an emission area 7 of the semiconductor body 2. The semiconductor body 2 is based on, for example, a nitride compound semiconductor material such as GaN. The semiconductor body 2 comprises an active region in which, in the intended operation, incoherent, electromagnetic primary radiation is generated. Here, the primary radiation is radiation of a first wavelength range.

The semiconductor body 2 comprises for example substantially the features of a so-called thin-film light-emitting diode chip. A basic principle of a thin-film light-emitting diode chip is described, for example, in the publication I. Schnitzer et al., Appl. Phys. Lett. 63 (16) 18.October 1993, pages 2174 - 2176, the disclosure content of which is hereby incorporated by reference. Examples of thin-film light-emitting diode chips are described in EP 0905797 A2 and WO 02/13281 A1, the disclosure content of which is insofar hereby also incorporated by reference. At least 50% or at least 70%, preferably at least 90% of the complete primary radiation emitted by the semiconductor body 2 is emitted via the emission area 7.

The first dielectric mirror layer 3 comprises a plurality of dielectric layers, for example between and including five and 20 layers, in a layer stack. In the layer stack, dielectric layers of a low refractive index material, such as SiO2, alternate with dielectric layers of a high refractive index material, such as TiO2 or Nb2O5. The layers each comprise a thickness between 10 nm and 500 nm, inclusive.

The first dielectric mirror layer 3 is configured to pass or transmit radiation of the first wavelength range incident at angles of incidence 9 in a first angular range, and to reflect radiation of the first wavelength range incident at angles of incidence 9 in a second angular range. The first angular range comprises, for example, angles of incidence between 0° and 30°, inclusive. The second angular range comprises, for example, angles of incidence between 30° and 90°.

The converter layer 4 is configured to convert electromagnetic radiation of the first wavelength range into electromagnetic radiation of a second wavelength range. The second wavelength range is red-shifted relative to the first wavelength range. For example, the first wavelength range and the second wavelength range do not overlap with each other. For example, the first wavelength range is a region from the blue spectral range and the second wavelength range is a region from the yellow spectral range. The converter layer 4 is arranged on a side of the dielectric mirror layer 3 facing away from the semiconductor body 2. Preferably, the first dielectric mirror layer 3 and the converter layer 4 are in direct contact with each other. Preferably, the converter layer 4 comprises a thickness, measured perpendicular to the main extension plane of the first dielectric mirror layer 3, of at least 5 µm and at most 500 µm. The converter layer 4 comprises, for example, converter particles, such as phosphors, embedded in a sol-gel matrix material or a water glass. In particular, the matrix material is cured. Alternatively, the converter layer 4 can be ceramic.

On a surface of the converter layer 4 facing away from the semiconductor body 2, the second dielectric mirror layer 5 is arranged. The second dielectric mirror layer 5 is configured to transmit radiation of the second wavelength range incident at angles of incidence 10 in the first angular range, and to reflect radiation of the second wavelength range incident at angles of incidence 10 in the second angular range. The first dielectric mirror layer 3 and the second dielectric mirror layer 5 differ, for example, in terms of the materials of the layers, the thicknesses of the layers, and/or the number of layers.

Due to the directional emission of electromagnetic radiation of the first wavelength range through the first dielectric mirror layer 3 and the directional emission of electromagnetic radiation of the second wavelength range through the second dielectric mirror layer 5, the complete semiconductor component 1 preferably emits mixed light with a directional radiation characteristic. The mixed light thereby comprises wavelengths of the first and second wavelength ranges. For example, the mixed light arouses a white color impression in a human observer.

A third mirror layer 8 is arranged on a surface of the semiconductor body 2 opposite to the emission area 7. The third mirror layer 8 comprises, for example, a dielectric mirror, such as a Bragg mirror, and/or a metallic mirror, which is based on silver, for example. The third mirror layer 8 is configured to reflect radiation, in particular radiation of the first and second wavelength range, which would leave the semiconductor body 2 at the surface opposite the emission area 7.

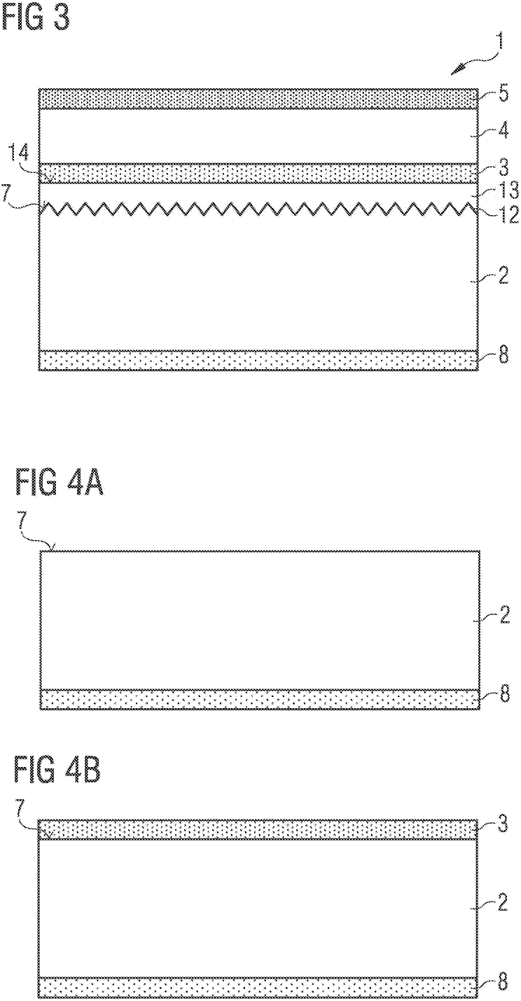

The semiconductor component 1 according to the exemplary embodiment of FIG. 2 comprises essentially the same features as the semiconductor component 1 of FIG. 1, with the difference that the converter layer 4 is arranged between the second dielectric mirror layer 5 and the emission area 7. Further, the first dielectric mirror layer 3 is arranged between the converter layer 4 and the second dielectric mirror layer 5. In addition, a fourth mirror layer 15 is arranged on side surfaces of the semiconductor body 2. Side surfaces of the semiconductor body 2 connect the emission area 7 with the surface on which the third mirror layer 8 is arranged. The fourth mirror layer 15 comprises in particular substantially the same materials as the third mirror layer 8 and comprises the same reflective properties. The first dielectric mirror layer 3 and the second dielectric mirror layer 5 together form an optical element 11. For example, the first dielectric mirror layer 3 and the second dielectric mirror layer 5 are integrally formed.

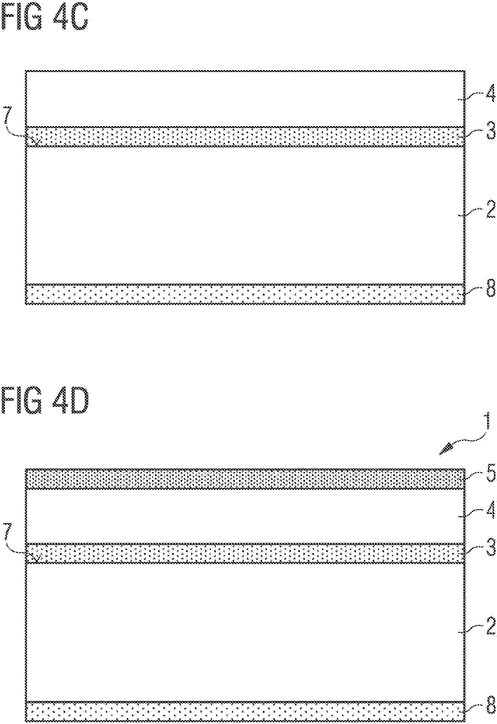

The semiconductor component 1 of FIG. 3 comprises essentially the same features as the semiconductor component of FIG. 1, with the difference that the emission area 7 comprises an outcoupling structure 12. Further, a planarization layer 13 is arranged at the outcoupling structure 12 in such a way that the outcoupling structure 12 is completely filled by the planarization layer 13. In particular, the planarization layer 13 forms a planarized main surface 14. The main surface 14 is thereby opposite to the outcoupling structure 12. For example, the planarization layer 13 comprises SiO2 and has been processed so that the main surface 14 is smooth. For example, the main surface 14 has been grinded and/or polished.

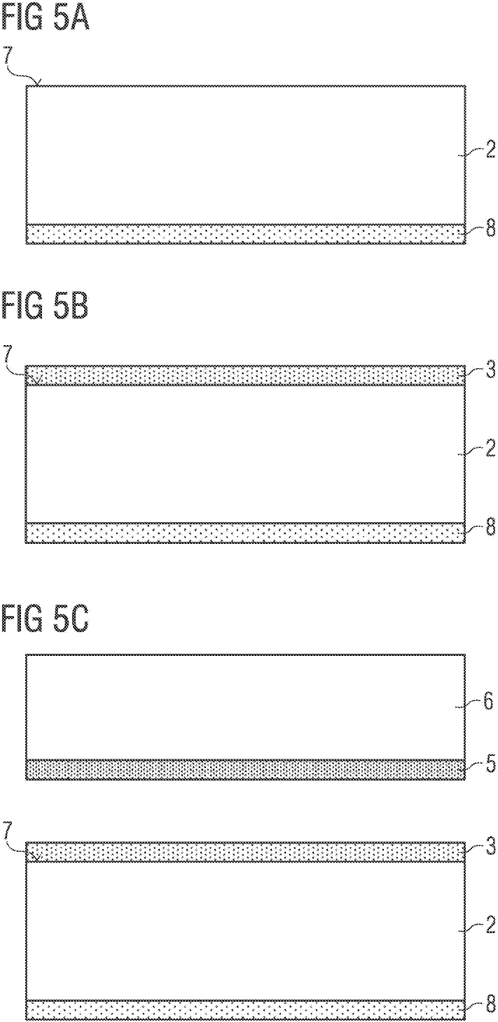

In the method according to the exemplary embodiment of FIGS. 4A to 4D for manufacturing a semiconductor component, a semiconductor body 2 is first provided (FIG. 4A). The semiconductor body 2 comprises an active region and comprises an emission area 7 and, on a surface opposite to the emission area, a third mirror layer 8. The third mirror layer 8 comprises, for example, a dielectric mirror, such as a Bragg mirror and/or a metallic mirror which is based, for example, on silver.

In a next step, a first dielectric mirror layer 3 is arranged on the emission area 7 (FIG. 4B). For example, a planarization layer, which is smoothed, is previously arranged on the emission area 7. For example, the first dielectric mirror layer 3 is deposited or applied by means of coating or sputtering.

In a further step of the method, a converter layer 4 is applied to a surface of the first dielectric mirror layer 3 facing away from the emission area 7 (FIG. 4C). For example, a surface of the converter layer 4 opposite the first dielectric mirror layer 3 is polished and/or grinded so that a smooth surface is formed.

In a next step, a second dielectric mirror layer 5 is deposited on a surface of the converter layer 4 facing away from the semiconductor body 2 (FIG. 4D). By depositing the second dielectric mirror layer 5, in particular, the semiconductor component 1 is completed. This semiconductor component 1 is for example the one of FIG. 1.

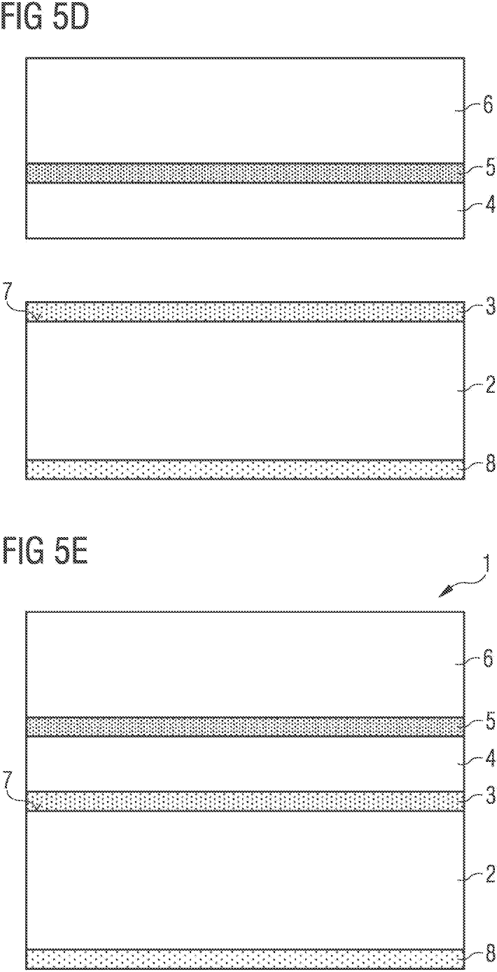

In the method according to the exemplary embodiment of FIGS. 5A to 5D, first, a semiconductor body 2 with an emission area 7 is provided (FIG. 5A). In a further method step, a first dielectric mirror layer 3 is arranged on the emission area 7 (FIG. 5B). The first dielectric mirror layer 3 is applied in particular by the same methods as the first dielectric mirror layer 3 of FIG. 4B.

In a further method step, a carrier element is provided. The carrier element is a glass body 6. A second dielectric mirror layer 5 is applied to a side of the glass body 6 (FIG. 5C).

In a further method step, a converter layer 4 is applied to a surface of the second dielectric mirror layer 5 facing away from the glass body 6 (FIG. 5D). The converter layer 4 comprises, for example, silicone with phosphor particles embedded therein.

In a further method step, the composite of glass substrate 6, second dielectric mirror layer 5 and converter layer 4 is applied directly to the first dielectric mirror layer 3 (FIG. 5E). This results in a completed semiconductor component 1 according to an exemplary embodiment, wherein the semiconductor component 1 comprises a glass body 6.

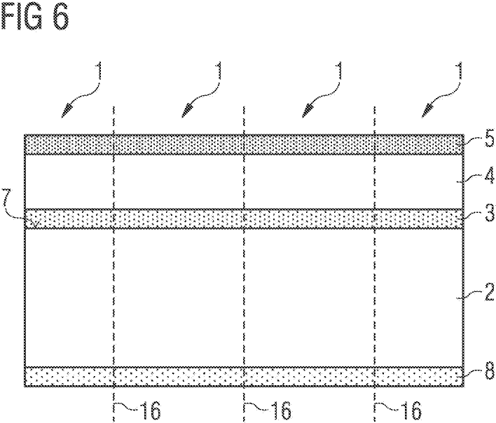

FIG. 6 shows a method step of a variant of the method of FIGS. 4A to 4D. In the variant of FIG. 6, a method according to the exemplary embodiment of FIGS. 4A to 4C is carried out for a composite of several semiconductor bodies 2. Following the stage shown in FIG. 4D, the composite is singulated using separation lines 16 (see FIG. 6). For example, the composite is singulated by sawing or etching, in particular plasma etching, or laser cutting or scribing and breaking. Due to the singulation a plurality of semiconductor components 1 is formed.

The invention is not limited to the embodiments by the description based thereon. Rather, the invention comprises any new feature as well as any combination of features, which in particular includes any combination of features in the patent claims, even if this feature or this combination itself is not explicitly stated in the patent claims or embodiments.

1-18. (canceled)

19. A semiconductor component configured to emit radiation of a first wavelength range and a second wavelength range, the semiconductor component comprising:
a semiconductor body having an active region configured to generate electromagnetic primary radiation and an emission area;
a first dielectric mirror layer;
a converter layer configured to convert radiation generated in the semiconductor component to radiation of the second wavelength range; and
a second dielectric mirror layer,
wherein the first dielectric mirror layer and the converter layer are arranged between the emission area and the second dielectric mirror layer,
wherein the first dielectric mirror layer is transmissive for radiation of the first wavelength range incident at angles of incidence in a predetermined first angular range and reflective for radiation of the first wavelength range incident at angles of incidence in a predetermined second angular range, and
wherein the second dielectric mirror layer is transmissive for radiation of the second wavelength range incident at angles of incidence in the first angular range and reflective for radiation of the second wavelength range incident at angles of incidence in the second angular range.

20. The semiconductor component according to claim 19,
wherein the first angular range comprises all angles of incidence between 0° and α, inclusive, measured to a normal of the respective dielectric mirror layer, and
wherein the second angular range comprises all angles of incidence of at least β measured with respect to the normal of the respective dielectric mirror layer, where β > α is true.

21. The semiconductor component according to claim 19,
wherein the emission area of the semiconductor body comprises an outcoupling structure,
wherein a planarization layer is arranged at the outcoupling structure, and
wherein the planarization layer completely fills the outcoupling structure so that the planarization layer comprises a smooth main surface facing away from the outcoupling structure.

22. The semiconductor component according to claim 19, wherein the converter layer is arranged between the first dielectric mirror layer and the second dielectric mirror layer.

23. The semiconductor component according to claim 19, wherein the first dielectric mirror layer is arranged between the converter layer and the second dielectric mirror layer.

24. The semiconductor component according to claim 23, wherein the first dielectric mirror layer and the second dielectric mirror layer are integrally formed as an optical element.

25. The semiconductor component according to claim 19, further comprising a third mirror layer arranged at a surface of the semiconductor body opposite the emission area.

26. The semiconductor component according to claim 19, wherein the converter layer comprises a thickness between 5 µm and 500 µm, inclusive.

27. The semiconductor component according to claim 19,
wherein the converter layer comprises converter particles embedded in an inorganic matrix material, and
wherein a surface of the converter layer facing away from the semiconductor body is smooth.

28. The semiconductor component according to claim 19,
wherein the converter layer is ceramic, and
wherein a surface of the converter layer facing away from the semiconductor body is smooth.

29. The semiconductor component according to claim 19, further comprising a glass body arranged on a surface of the second dielectric mirror layer facing away from the semiconductor body.

30. A method for manufacturing a semiconductor component, the method comprising:
providing at least one semiconductor body;
depositing a first dielectric mirror layer on an emission area of the semiconductor body, wherein the first dielectric mirror layer is transmissive for radiation of a first wavelength range incident at angles of incidence in a predetermined first angular range and reflective for radiation of the first wavelength range incident at angles of incidence in a predetermined second angular range;
depositing a converter layer on the emission area, wherein the converter layer is configured to convert radiation generated in the semiconductor component into radiation of a second wavelength range; and
depositing a second dielectric mirror layer on the emission area, wherein the second dielectric mirror layer is transmissive for radiation of the second wavelength range incident at angles of incidence in the first angular range and reflective for radiation of the second wavelength range incident at angles of incidence in the second angular range.

31. The method according to claim 30, wherein depositing the first dielectric mirror layer, depositing the converter layer and depositing the second dielectric mirror layer are performed in the indicated order so that the converter layer is arranged between the first dielectric mirror layer and the second dielectric mirror layer.

32. The method according to claim 30, wherein depositing the first dielectric mirror layer is carried out after depositing the converter layer and before depositing the second dielectric mirror layer so that the first dielectric mirror layer is arranged between the converter layer and the second dielectric mirror layer.

33. The method according to claim 30,
wherein the first dielectric mirror layer is deposited on a first side of the converter layer,
wherein the second dielectric mirror layer is deposited on a second side of the converter layer opposite the first side, and
wherein, subsequently, a composite of the converter layer and the dielectric mirror layers is applied on the emission area.

34. The method according to claim 30, further comprising providing a carrier element, wherein the second dielectric mirror layer is applied to the carrier element, and wherein, subsequently, a composite comprising the carrier element and the second dielectric mirror layer is applied to the emission area.

35. The method according to claim 34, further comprising removing the carrier element.

36. The method according to claim 30, wherein providing the at least one semiconductor body comprises providing a composite of a plurality of semiconductor bodies, and wherein the method further comprises, after deposing the first dielectric mirror layer, deposing the converter layer and deposing the second dielectric mirror layer, singulating the composite of the semiconductor bodies.
